(19) United States
(12) Patent Application Publication
(10) Pub. No.: US 2022/0310618 A1
(43) Pub. Date: Sep. 29, 2022

(54) METHOD FOR FORMING FILM LAYER WITH UNIFORM THICKNESS DISTRIBUTION AND SEMICONDUCTOR STRUCTURE

(71) Applicant: CHANGXIN MEMORY TECHNOLOGIES, INC., Hefei City, Anhui Province (CN)

(72) Inventors: Tao CHEN, Hefei (CN); Cheng Yeh HSU, Hefei (CN); WenHao Hsieh, Hefei (CN)

(73) Assignee: CHANGXIN MEMORY TECHNOLOGIES, INC., Hefei City, Anhui Province (CN)

(21) Appl. No.: 17/430,410

(22) PCT Filed: Mar. 1, 2021
(86) PCT No.: PCT/CN2021/078405

§ 371 Date: Aug. 12, 2021

(30) Foreign Application Priority Data
Mar. 10, 2020 (CN) 202010160467.8

(51) Int. Cl. H01L 27/108

(52) U.S. Cl. CPC H01L 27/10811; H01L 27/10891; H01L 27/10829

(57) ABSTRACT

The present application relates to the technical field of semiconductor manufacturing, in particular to a method for forming a film layer with uniform thickness distribution and a semiconductor structure. The method for forming a film layer with uniform thickness distribution comprises: providing a substrate, a non-flat surface for forming a film layer being provided in the substrate; forming a first sub-layer on the non-flat surface at a first temperature by an in-situ steam generation process; and, forming a second sub-layer on a surface of the first sub-layer at a second temperature by an in-situ steam generation process, the film layer at least comprising the first sub-layer and the second sub-layer, the second temperature being higher than the first temperature.

### CROSS-REFERENCE TO RELATED APPLICATIONS

The present application claims the priority to the Chinese patent application 202010160467.8, titled “METHOD FOR FORMING FILM LAYER WITH UNIFORM THICKNESS DISTRIBUTION AND SEMICONDUCTOR STRUCTURE”, filed on Mar. 10, 2020, which is incorporated herein by reference in its entirety.

### TECHNICAL FIELD

The present application relates to the technical field of semiconductor manufacturing, in particular to a method for forming a film layer with uniform thickness distribution and a semiconductor structure.

### BACKGROUND

Dynamic random access memories (DRAMs), as semiconductor structures commonly used in electronic devices such as computers, comprise a plurality of storage units, each of which usually comprises a transistor and a capacitor. Gates of the transistors are electrically connected to word lines, sources thereof are electrically connected to bit lines, and drains thereof are electrically connected to the capacitors.

The word line voltages on the word lines can control on and off of the transistors, so that data information stored in the capacitors can be read or data information can be written into the capacitors by using the word lines.

In the DRAM manufacturing process, a word line-gate oxide layer is formed by in-situ stream generation (ISSG), where a reaction gas is fed at a low pressure and then quickly heated to a higher temperature at one time, so that the reaction gas generates free radicals on the surface of the substrate and then reacts with the substrate to generate the gate oxide layer by using the free radicals. However, the gate oxide layer formed by this method is not uniform in thickness. Thus, on one hand, centralization of local electric fields on the gate will be caused, it is likely to cause internal discharging to form many conductive paths, and the breakdown voltage is reduced. On the other hand, in a case where there are positive charges in the gate oxide layer, the local electric field is very strong in a region with a small thickness, and the tunnel current will be produced when a negative gate voltage is applied, resulting in leakage current.

Therefore, how to improve the uniformity of thickness distribution of a film layer on a non-flat surface and improve the breakdown and electric leakage of the film layer is a technical problem to be solved urgently at present.

### SUMMARY

The present application provides a method for forming a film layer with uniform thickness distribution, to solve the problem that a film layer formed on a non-flat surface is prone to breakdown and electric leakage due to its non-uniform thickness and improve the performance of semiconductor structures.

In order to solve the problem mentioned above, the present application provides a method for forming a film layer with uniform thickness distribution, comprising: providing a substrate, a non-flat surface for forming a film layer being provided in the substrate; forming a first sub-layer on the non-flat surface at a first temperature by an in-situ steam generation process; and forming a second sub-layer on a surface of the first sub-layer at a second temperature by an in-situ steam generation process; the film layer at least comprising the first sub-layer and the second sub-layer, the second temperature being higher than the first temperature.

Optionally, a trench is formed in the substrate, and the non-flat surface is an inner wall of the trench; and, the forming a first sub-layer on the non-flat surface at a first temperature by an in-situ steam generation process comprises:

feeding reaction gas into a reaction chamber in which the substrate is accommodated; and

raising a temperature in the reaction chamber to the first temperature, and forming the first sub-layer on a surface of the inner wall of the trench, the first sub-layer on a sidewall of the trench having a same thickness as the first sub-layer on a bottom of the trench.

Optionally, the first sub-layer has a thickness of 0.5 nm to 2 nm.

Optionally, the forming a second sub-layer on the surface of the first sub-layer at a second temperature by an in-situ steam generation process comprises:

continuously feeding the reaction gas and raising the temperature in the reaction chamber to the second temperature, and forming the second sub-layer covering the surface of the first sub-layer, the second sub-layer on a side surface of the first sub-layer having a same thickness as the second sub-layer on a bottom surface of the first sub-layer.

Optionally, the trench before formation of the first sub-layer has a first feature size of 12 nm to 40 nm;

the trench after formation of the first sub-layer has a second feature size of 11 nm to 40 nm, and the first feature size is greater than the second feature size; and

the trench after formation of the second sub-layer has a third feature size of 11 nm to 40 nm, and the second feature size is greater than the third feature size.

Optionally, the trench before formation of the first sub-layer has a first depth of 110 nm to 280 nm;

the trench after formation of the first sub-layer has a second depth of 110 nm to 280 nm, and the first depth is greater than the second depth; and

the trench after formation of the second sub-layer has a third depth of 110 nm to 280 nm, and the second depth is greater than the third depth.

Optionally, the thickness of the first sub-layer is less than or equal to the thickness of the second sub-layer.

Optionally, the first temperature is not more than 750° C., and the second temperature is not less than 1000° C.

Optionally, flow of the reaction gas and/or reaction time in process of forming the first sub-layer at the first temperature is different from the flow of the reaction gas and/or the reaction time in process of forming the second sub-layer at the second temperature.

Optionally, the method further comprising:

stopping feeding the reaction gas, and annealing the film layer formed on the non-flat surface at a high temperature.

In order to solve the problem mentioned above, the present application further provides a semiconductor, comprising:

a substrate, a non-flat surface being provided in the substrate; and

a film layer, located on the non-flat surface, the film layer being formed by the method for forming a film layer with uniform thickness distribution described above.

For the method for forming a film layer with uniform thickness distribution and the semiconductor structure according to the present application, the film layer is formed on the non-flat surface by at least two steps. In the first step, the first sub-layer is formed at a lower first temperature, so that the generation of free radicals for reaction is reduced, an excessive reaction rate is restrained, and the first sub-layer generated on the non-flat surface has uniform thickness. In the second step, the second sub-layer covering the first sub-layer is formed at a second temperature that is higher than the first temperature. The finally formed film layer is a multilayer structure at least comprising the first sub-layer and the second sub-layer. The overall thickness distribution of the film layer located on the non-flat surface is uniform, so that the breakdown and electric leakage of the film layer are improved, and the electrical properties of semiconductor structures are improved.

### BRIEF DESCRIPTION OF THE DRAWINGS

FIG. 1 is a flowchart of a method for forming a film layer with uniform thickness distribution in a specific implementation of the present application; and

FIGS. 2A-2F are sectional views of main processes during forming a film layer with uniform thickness distribution in a specific implementation of the present application.

### DETAILED DESCRIPTION

The specific implements of the method for forming a film layer with uniform thickness distribution and the semiconductor structure according to the present application will be described in detail below with reference to the accompanying drawings.

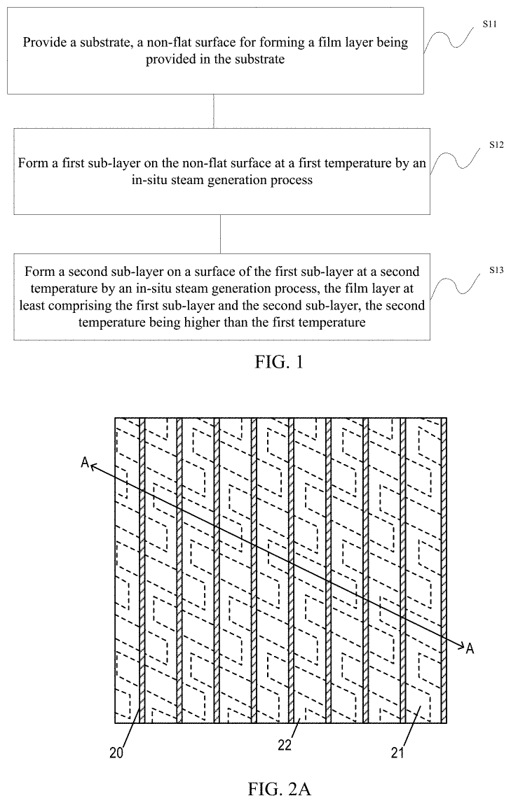

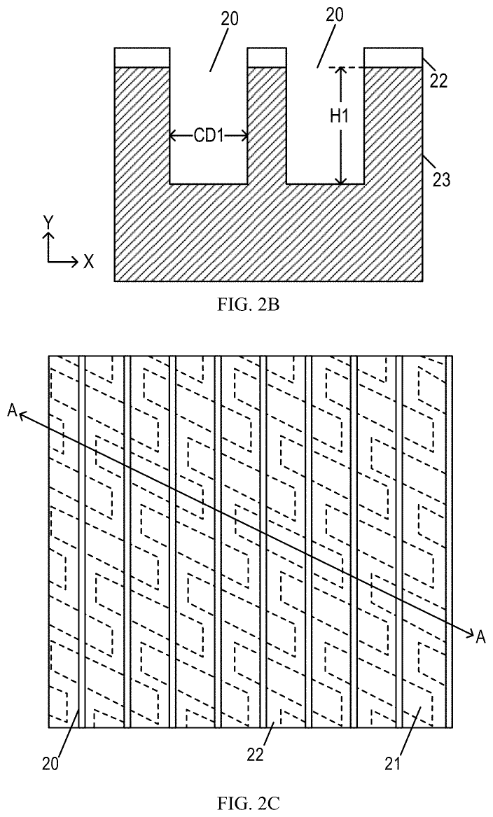

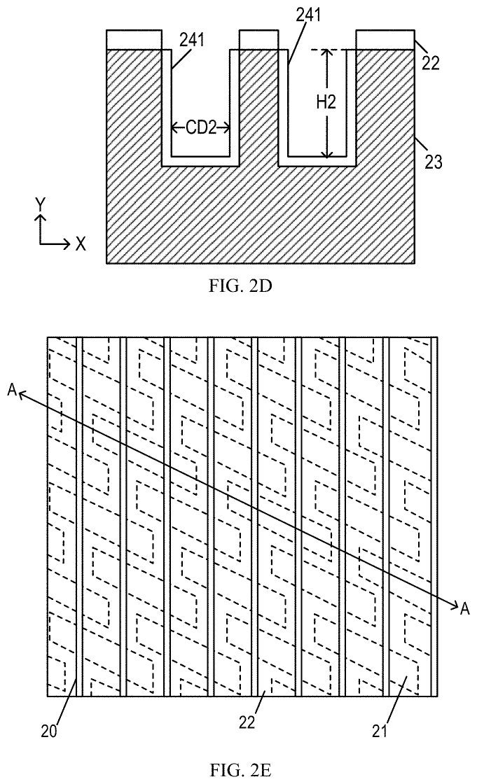

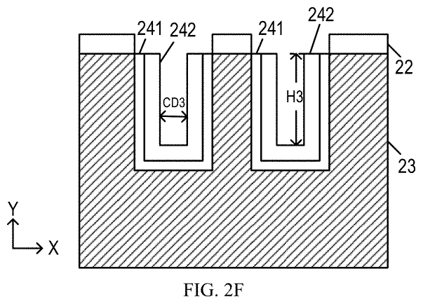

This specific implementation provides a method for forming a film layer with uniform thickness distribution. FIG. 1 is a flowchart of the method for forming a film layer with uniform thickness distribution in a specific implementation of the present application, and FIGS. 2A-2F are sectional views of main processes during forming a film layer with uniform thickness distribution in a specific implementation of the present application. As shown in FIGS. 1 and 2A-2F, the method for forming a film layer with uniform thickness distribution in this specific implementation comprises following steps.

S11: A substrate 23 is provided, a non-flat surface for forming a film layer being provided in the substrate 23, as shown in FIGS. 2A and 2B, wherein FIG. 2B is a partial sectional view in the direction AA in FIG. 2A.

The material of the substrate 23 may be, but not limited to, silicon. By taking a substrate in a DRAM as an example, a plurality of active regions 21 arranged in a matrix are provided inside the substrate 23. In this specific implementation, the non-flat surface refers to a surface with various different heights in a direction perpendicular to the substrate. In this specific implementation, said plurality refers to more than two. The non-flat surface may be an etched structure formed by etching the substrate 23. For example, a mask layer 22 with an etching window is covered on the surface of the substrate 23, and the substrate 23 is etched along the etching window by a dry etching process or a wet etching process to form the trench 20. The inner wall of the trench 20 (the sidewall and bottom of the trench 20 are different in height) is a non-flat surface used for forming the film layer subsequently.

S12: A first sub-layer 241 is formed on the non-flat surface at a first temperature by an in-situ steam generation process, as shown in FIGS. 2C and 2D, wherein FIG. 2D is a partial sectional view in the direction AA in FIG. 2C.

Optionally, a trench 20 is formed in the substrate 23, and the non-flat surface is an inner wall of the trench 20. The specific step of forming a first sub-layer 241 on the non-flat surface at a first temperature by an in-situ steam generation process comprises: feeding reaction gas into a reaction chamber in which the substrate 23 is accommodated; and

raising the temperature in the reaction chamber to the first temperature, and forming the first sub-layer 241 in the trench 20, the first sub-layer 241 on the sidewall of the trench 20 having the same thickness as the first sub-layer 241 on the bottom of the trench 20.

The following description will be given by taking the substrate 23 being made of a silicon material, the first sub-layer 241 being made of a silicon oxide material and the film layer being a gate oxide layer as an example. In the in-situ steam generation process, oxygen free radicals react with silicon atoms on the surface of the trench 20. When a mixed gas of hydrogen and oxygen as the reaction gas is transported to the reaction chamber, with the increase of the temperature, hydrogen reacts with oxygen to generate a large number of gas-phase reactive free radicals with oxidizing property. These free radicals comprise reactive oxygen atoms, atomic oxygen, water molecules, hydroxyl groups or the like. Subsequently, these free radicals participate in the oxidization process of the silicon material. In this specific implementation, the temperature in the reaction chamber is firstly raised to a relatively low first temperature, so that the generation rate of oxygen free radicals on the surface of the inner wall of the trench 20 can be reduced to a certain extent, and the reaction rate of the oxygen free radicals and the silicon material can be thus reduced. At this time, the generation rate of the first sub-layer 241 is mainly influenced by the gas-flow rate of hydrogen and oxygen. The concentrations of hydrogen and oxygen on the sidewall and bottom of the trench 20 has little influence on the generation rate of the first sub-layer 241, so that the difference in the generation rates of the first sub-layer 241 between the sidewall and the bottom of the trench 20 is significantly reduced, and the first sub-layer 241 with a uniform thickness is thus formed on the whole inner wall (including the sidewall of the trench 20 and the bottom of the trench 20) of the trench 20.

The specific numerical value of the first temperature can be set by those skilled in the art according to actual needs, as long as the reaction rate of the reaction gas and the substrate (for example, an excessive reaction rate of the oxygen free radicals and the silicon material) can be restrained, so that the first sub-layer 241 on the sidewall of the trench 20 has the same thickness as the first sub-layer 241 on the bottom of the trench 20.

Optionally, the first sub-layer 241 has a thickness of 0.5 nm to 2 nm.

S13: A second sub-layer 242 is formed on the surface of the first sub-layer 241 at a second temperature by an in-situ steam generation process, the film layer at least comprising the first sub-layer 241 and the second sub-layer 241, the second temperature being higher than the first temperature, as shown in FIGS. 2E and 2F, wherein FIG. 2F is a partial sectional view in the direction AA in FIG. 2E.

Optionally, the specific step of forming a second sub-layer 242 on the surface of the first sub-layer 241 at a second temperature by an in-situ steam generation process comprises:

continuously feeding the reaction gas and raising the temperature in the reaction chamber to the second temperature, and forming the second sub-layer 242 covering the surface of the first sub-layer 242, the second sub-layer 242 on a side surface of the first sub-layer 241 having the same thickness as the second sub-layer on a bottom surface of the first sub-layer 241.

The following description will be given by taking the substrate 23 being made of a silicon material, the non-flat surface being the inner wall of the trench, both the first sub-layer 241 and the second sub-layer 242 being made of a silicon oxide material and the film layer being a gate oxide layer as an example. After finishing the growing of the first sub-layer 241, the temperature in the reaction chamber is rapidly raised to the second temperature while continuously feeding the reaction gas, so that the second sub-layer 242 is continuously generated on the surface of the first sub-layer 241. Since the first sub-layer 241 has been generated on the inner wall of the trench 20 before generating the second sub-layer 242, the reaction rate is mainly influenced by oxygen free radicals entering the silicon surface, that is, the generation rate of the second sub-layer 242 is mainly influenced by the diffusion rates of hydrogen and oxygen. However, since the difference in the diffusion rates of hydrogen and oxygen between the sidewall and the bottom of the trench 20, the thickness of the second sub-layer 242 generated on the whole surface of the first sub-layer 241 is relatively uniform, that is, the thickness of the second sub-layer 242 corresponding to the sidewall of the trench 20 is the same as the thickness of the second sub-layer 242 corresponding to the bottom of the trench 20.

Since the thickness of the first sub-layer 241 generated at the first temperature on the sidewall of the trench 20 is the same as that of the first sub-layer on the bottom of the trench 20 and the thickness of the second sub-layer 242 generated at the second temperature on the sidewall of the trench 20 is the same as that of the second sub-layer on the bottom of the trench 20, the first sub-layer 241 and the second sub-layer 242 as a whole have the same thickness on the sidewall of the trench 20 and on the bottom of the trench 20. That is, after the process of generating the second sub-layer 242 is completed, the film layer already formed on the inner wall of the trench 20 has a uniform thickness distribution.

Optionally, the trench 20 before formation of the first sub-layer 241 has a first feature size CD1 of 12 nm to 40 nm;

the trench 20 after formation of the first sub-layer 241 has a second feature size CD2 of 11 nm to 40 nm, and the first feature size CD1 is greater than the second feature size CD2; and the trench 20 after formation of the second sub-layer 242 has a third feature size CD3 of 11 nm to 40 nm, and the second feature size CD2 is greater than the third feature size CD3.

Optionally, the trench 20 before formation of the first sub-layer 241 has a first depth H1 of 110 nm to 280 nm;

the trench 20 after formation of the first sub-layer 241 has a second depth H2 of 110 nm to 280 nm, and the first depth H1 is greater than the second depth H2; and

the trench 20 after formation of the second sub-layer 242 has a third depth H3 of 110 nm to 280 nm, and the second depth H2 is greater than the third depth H3.

Specifically, before formation of the first sub-layer 241, the trench 20 has an inner diameter (i.e., first feature size CD1) of 12 nm to 40 nm and a first depth H1 of 110 nm to 280 nm. After formation of the first sub-layer 241 and before formation of the second sub-layer 242, the trench 20 has an inner diameter (i.e., second feature size CD2) of 11 nm to 40 nm and a second depth H2 of 110 nm to 280 nm. After formation of the second sub-layer 242, the trench 20 has an inner diameter (i.e., third feature size CD3) of 11 nm to 20 nm and a third depth H3 of 110 nm to 280 nm.

Optionally, the thickness of the first sub-layer 241 is less than or equal to that of the second sub-layer 242.

Specifically, since the first sub-layer 241 is generated to restrain the excessive reaction rate and allow the generated second sub-layer 242 to have a uniform thickness on the sidewall and bottom of the trench 20, and the overall reaction rate at the second temperature is higher than the overall reaction rate at the first temperature, the thickness of the first sub-layer 241 may be less than or equal to the thickness of the second sub-layer 242, so that the overall generation efficiency of the gate oxide layer is improved and the manufacturing time of semiconductors is shortened.

In other specific implementations, those skilled in the art can also control the thickness of the first sub-layer to be greater than the thickness of the second sub-layer, and those skilled in the art can make a choice according to actual needs.

Optionally, the first temperature is not more than 750° C., and the second temperature is not less than 1000° C. Those skilled in the art can also select other temperature values according to actual needs.

Specifically, the specific numerical values of the first temperature and the second temperature and the difference between the first temperature and the second temperature can be set by those skilled in the art according to actual needs, as long as it is ensured that the difference between the first temperature and the second temperature is at least 250° C. For example, the first temperature may be 750° C., 730° C., 700° C., 680° C., 650° C. or 630° C.; and correspondingly, the second temperature may be 1130° C., 1100° C., 1080° C., 1050° C., 1030° C. or 1000° C.

Optionally, the flow of the reaction gas and/or the reaction time in the process of forming the first sub-layer at the first temperature is different from the flow of the reaction gas and/or the reaction time in the process of forming the second sub-layer at the second temperature.

Specifically, the growth rates of the first sub-layer and the second sub-layer and the relative thicknesses of the first sub-layer and the second sub-layer can be controlled by adjusting first reaction parameters in the process of forming the first sub-layer at the first temperature and second reaction parameters in the process of forming the second sub-layer at the second temperature, so that the film layer with a preset thickness is generated, wherein the first reaction parameters and the second reaction parameters comprise the rate or flow of the reaction gas (for example, hydrogen and oxygen) fed into the reaction chamber, the reaction time or the like. For example, the thickness of the first sub-layer can be decreased by shortening the reaction time of the generation reaction of the first sub-layer. Correspondingly, the thickness of the second sub-layer can be increased by prolonging the reaction time of the generation reaction of the second sub-layer. By adjusting the relative thickness relationship between the first sub-layer and the first sub-layer, a film layer with a preset thickness is generated.

Optionally, after forming a second sub-layer 242 on the surface of the first sub-layer 241 at a second temperature by an in-situ steam generation process, the method further comprises following steps:

stopping feeding the reaction gas, and annealing the film layer at a high temperature.

Specifically, after the process of generating the second sub-layer 242 is completed, the formed film layer is immediately annealed at a high temperature to repair lattice defects and surface defects of the film layer, thereby improving the quality of the film layer. At the end of annealing, the temperature in the reaction chamber is slowly lowered to an annealing temperature, so that the whole manufacturing process of the film layer is completed. The annealing temperature is lower than the first temperature. For example, the annealing temperature is 300° C.

This specific implementation is described by taking the film layer being a two-layer structure comprising the first sub-layer and the second sub-layer as an example. Those skilled in the art can also set a plurality of sequentially increasing temperature values according to actual needs, for example, sequentially increasing a first temperature, a second temperature, a third temperature, a fourth temperature, a fifth temperature or the like. The difference between any two adjacent temperature values may be equal (that is, a plurality of temperature values increase at equal intervals, for example, at an interval of 250° C. or 300° C.) or unequal (for example, the difference between later adjacent temperature values is smaller). After the second sub-layer is formed at the second temperature, a third sub-layer may be formed on the surface of the second sub-layer at a third temperature higher than the second temperature by an in-situ steam generation process; then, a fourth sub-layer is formed on the surface of the third sub-layer at a fourth temperature higher than the third temperature by an in-situ steam generation process; and by that analogy, a desired number of sub-layers are formed. By forming a plurality of sub-layers, on one hand, the total thickness of the film layer can be adjusted more accurately; on the other hand, it is advantageous to repair lattice defects inside the film layer and improve the quality of the film layer. The thickness of each sub-layer may be the same or different, and may be adjusted by those skilled in the art by adjusting reaction parameters such as the flow of the reaction gas and the reaction time. The finally formed film layer is a multi-layer structure comprising sub-layers formed at various temperatures, for example, a first sub-layer, a second sub-layer, a third sub-layer, a fourth sub-layer and the like. In this specific implementation, said plurality of layers refer to more than two layers.

Moreover, this specific implementation further provides a semiconductor structure, comprising:

a substrate 23, a non-flat surface being provided in the substrate 23; and

a film layer, located on the non-flat surface, the film layer being formed by the method for forming a film layer with uniform thickness distribution described above.

For the method for forming a film layer with uniform thickness distribution and the semiconductor structure in this specific implementation, the film layer is formed on the non-flat surface by at least two steps. In the first step, the first sub-layer is formed at a lower first temperature, so that the generation of free radicals for reaction is reduced, an excessive reaction rate is inhibited, and the first sub-layer generated on the non-flat surface has uniform thickness. In the second step, the second sub-layer covering the first sub-layer is formed at a second temperature that is higher than the first temperature. The finally formed film layer is a multilayer structure at least comprising the first sub-layer and the second sub-layer. The overall thickness distribution of the film layer located on the non-flat surface is uniform, so that the breakdown and electric leakage of the film layer are improved, and the electrical properties of semiconductor structures are improved.

The above description merely shows the preferred implementations of the present application. It should be noted that for a person of ordinary skill in the art, various improvements and modifications may be made without departing from the principle of the present application, and those improvements and modifications shall also be regarded as falling into the protection scope of the present application.

1. A method for forming a film layer with uniform thickness distribution, comprising:
providing a substrate, a non-flat surface for forming a film layer being provided in the substrate;
forming a first sub-layer on the non-flat surface at a first temperature by an in-situ steam generation process; and
forming a second sub-layer on a surface of the first sub-layer at a second temperature by an in-situ steam generation process;
wherein the film layer at least comprises the first sub-layer and the second sub-layer, and the second temperature is higher than the first temperature.

2. The method for forming a film layer with uniform thickness distribution according to claim 1, wherein a trench is formed in the substrate, and the non-flat surface is an inner wall of the trench; and the forming a first sub-layer on the non-flat surface at a first temperature by an in-situ steam generation process comprises:
feeding reaction gas into a reaction chamber in which the substrate is accommodated; and
raising a temperature in the reaction chamber to the first temperature, and forming the first sub-layer on a surface of the inner wall of the trench, the first sub-layer on a sidewall of the trench having a same thickness as the first sub-layer on a bottom of the trench.

3. The method for forming a film layer with uniform thickness distribution according to claim 2, wherein the first sub-layer has a thickness of 0.5 nm to 2 nm.

4. The method for forming a film layer with uniform thickness distribution according to claim 2, wherein the forming a second sub-layer on the surface of the first sub-layer at a second temperature by an in-situ steam generation process comprises:
continuously feeding the reaction gas and raising the temperature in the reaction chamber to the second temperature, and forming the second sub-layer covering the surface of the first sub-layer, the second sub-layer on a side surface of the first sub-layer having a same thickness as the second sub-layer on a bottom surface of the first sub-layer.

5. The method for forming a film layer with uniform thickness distribution according to claim 2, wherein the trench before formation of the first sub-layer has a first feature size of 12 nm to 40 nm;
the trench after formation of the first sub-layer has a second feature size of 11 nm to 40 nm, and the first feature size is greater than the second feature size; and
the trench after formation of the second sub-layer has a third feature size of 11 nm to 40 nm, and the second feature size is greater than the third feature size.

6. The method for forming a film layer with uniform thickness distribution according to claim 2, wherein the trench before formation of the first sub-layer has a first depth of 110 nm to 280 nm;
the trench after formation of the first sub-layer has a second depth of 110 nm to 280 nm, and the first depth is greater than the second depth; and
the trench after formation of the second sub-layer has a third depth of 110 nm to 280 nm, and the second depth is greater than the third depth.

7. The method for forming a film layer with uniform thickness distribution according to claim 1, wherein the thickness of the first sub-layer is less than or equal to the thickness of the second sub-layer.

8. The method for forming a film layer with uniform thickness distribution according to claim 1, wherein the first temperature is not more than 750° C., and the second temperature is not less than 1000° C.

9. The method for forming a film layer with uniform thickness distribution according to claim 1, wherein flow of the reaction gas and/or reaction time in process of forming the first sub-layer at the first temperature is different from the flow of the reaction gas and/or the reaction time in process of forming the second sub-layer at the second temperature.

10. The method for forming a film layer with uniform thickness distribution according to claim 1, further comprising:
stopping feeding the reaction gas, and annealing the film layer formed on the non-flat surface at a high temperature.

11. A semiconductor structure, comprising:
a substrate, a non-flat surface being provided in the substrate; and
a film layer, located on the non-flat surface, the film layer being formed by the method for forming a film layer with uniform thickness distribution according to claim 1.

12. A semiconductor structure, comprising:
a substrate, a non-flat surface being provided in the substrate; and
a film layer, located on the non-flat surface, the film layer being formed by the method for forming a film layer with uniform thickness distribution according to claim 2.

13. A semiconductor structure, comprising:
a substrate, a non-flat surface being provided in the substrate; and
a film layer, located on the non-flat surface, the film layer being formed by the method for forming a film layer with uniform thickness distribution according to claim 3.

14. A semiconductor structure, comprising:
a substrate, a non-flat surface being provided in the substrate; and
a film layer, located on the non-flat surface, the film layer being formed by the method for forming a film layer with uniform thickness distribution according to claim 4.

15. A semiconductor structure, comprising:
a substrate, a non-flat surface being provided in the substrate; and
a film layer, located on the non-flat surface, the film layer being formed by the method for forming a film layer with uniform thickness distribution according to claim 5.

16. A semiconductor structure, comprising:
a substrate, a non-flat surface being provided in the substrate; and
a film layer, located on the non-flat surface, the film layer being formed by the method for forming a film layer with uniform thickness distribution according to claim 6.

17. A semiconductor structure, comprising:
a substrate, a non-flat surface being provided in the substrate; and
a film layer, located on the non-flat surface, the film layer being formed by the method for forming a film layer with uniform thickness distribution according to claim 7.

18. A semiconductor structure, comprising:
a substrate, a non-flat surface being provided in the substrate; and
a film layer, located on the non-flat surface, the film layer being formed by the method for forming a film layer with uniform thickness distribution according to claim 8.

19. A semiconductor structure, comprising:
a substrate, a non-flat surface being provided in the substrate; and
a film layer, located on the non-flat surface, the film layer being formed by the method for forming a film layer with uniform thickness distribution according to claim 9.

20. A semiconductor structure, comprising:
a substrate, a non-flat surface being provided in the substrate; and
a film layer, located on the non-flat surface, the film layer being formed by the method for forming a film layer with uniform thickness distribution according to claim 10.
